(19) United States
(12) Patent Application Publication
(10) Pub. No.: US 2023/0298772 A1
(43) Pub. Date: Sep. 21, 2023

(54) NUCLEAR FUEL CLADDING ELEMENT AND METHOD OF MANUFACTURING SAID CLADDING ELEMENT

(71) Applicant: FRAMATOME, COURBEVOIE (FR)

(72) Inventors: Pierre BARBERIS, UGINE (FR); Jeremy BISCHOFF, LYON (FR); Karl BUCHANAN, GENAS (FR)

(21) Appl. No.: 18/018,543

(22) PCT Filed: Jul. 29, 2021
(86) PCT No.: PCT/EP2021/071314

§ 371 Date: Jan. 27, 2023

(30) Foreign Application Priority Data
Jul. 31, 2020 (FR) FR2008183

(51) Int. Cl. G21C 3/07; G21C 3/20; G21C 3/04

(52) U.S. Cl. CPC G21C 3/07; G21C 3/20; G21C 3/045

(57) ABSTRACT

A nuclear fuel cladding element comprises a substrate made of a material containing zirconium and a protective coating covering the substrate on the outside. The protective coating is being made of a material containing chromium, and has a columnar microstructure composed of columnar grains and having on the outer surface thereof a microdroplet density of less than 100 per mm2.

The present disclosure relates to the field of nuclear fuel cladding, in particular nuclear fuel rod cladding, and to the manufacturing process thereof.

### BACKGROUND

The nuclear fuel including the fissile material is generally contained in a sealed cladding which prevents the dispersion of the nuclear fuel.

Nuclear fuel assemblies used in light water reactors generally comprise a bundle of nuclear fuel rods, each nuclear fuel rod comprising a cladding containing nuclear fuel, the cladding being formed of a cladding tube closed by a plug at each of the two ends thereof.

The cladding tubes of the nuclear fuel assemblies are made e.g. of zirconium or of an alloy containing zirconium. Such alloys have high performance under normal conditions of use in nuclear reactors. However, they can reach the limits thereof in particular in terms of temperature during severe accident conditions, such as e.g. during a Loss of Coolant Accident (or LOCA).

During such an event, the temperature can reach more than 800° C. and the cooling fluid is essentially in the form of water vapor. This can cause a rapid degradation of the cladding tube, in particular a release of hydrogen and a rapid oxidation of the cladding tube leading to the weakening thereof or even to the bursting thereof, and thus to the release of nuclear fuel out of the cladding. During oxidation, part of the hydrogen produced is absorbed (hydriding) by the cladding, entailing the weakening of the latter.

WO2016/042262A1 proposes a nuclear fuel cladding comprising a substrate made of zirconium or zirconium alloy and covered with a protective coating made of chromium or chromium alloy, the protective coating having a columnar microstructure.

### SUMMARY

One of the aims of the present disclosure is to propose a nuclear fuel cladding element which has satisfactory resistance to hydriding and/or oxidation.

To this end, the present disclosure proposes a nuclear fuel cladding element, the cladding element comprising a substrate made of a material containing zirconium and a protective coating covering the substrate on the outside, the protective coating being made of a material containing chromium, wherein the protective coating has a columnar microstructure composed of columnar grains and has on the outer surface thereof a microdroplet density of less than 100 per mm².

The columnar microstructure allows obtaining a ductile protective coating which can resist deformation, which limits the risk of occurrence of cracks in the event of deformation of the cladding element. The occurrence of a crack would be likely to expose the substrate to the outer environment, which could cause the degradation thereof and the weakening thereof, and ultimately lead to an opening of the cladding element.

Limiting the density of the microdroplets present on the surface of the protective coating further improves the resistance of the cladding element. Indeed, the presence of microdroplets limits the protection provided by the protective coating by allowing the cooling fluid to infiltrate along the boundaries of the microdroplets, reducing the corrosion and oxidation resistance of the cladding element, in particular, at high temperatures. Microdroplets are discontinuities in the microstructure of the protective coating, which form points of weakness and are likely to initiate cracks in the protective coating. Furthermore, the presence of microdroplets affects at least locally, the microstructure of the protective coating, the columnar grains generally having a larger mean diameter under the microdroplets.

According to particular embodiments, the cladding element comprises one or a plurality of the following optional features, taken individually or in all technically possible combinations:
next to and/or at the interface between the cladding element and the protective element, the columnar grains have a mean diameter less than or equal to 1 μm, preferentially less than or equal to 0.5 μm;
next to and/or on the outer surface of the protective coating, the columnar grains have a mean diameter between 0.05 μm and 5 μm, preferentially between 0.1 μm and 2 μm;
the microdroplets have a diameter less than or equal to 20 μm;
the protective coating has a thickness comprised between 5 μm and 25 μm.
the protective coating is made of a material containing chromium, e.g. pure chromium or an alloy containing chromium, e.g. a binary chromium alloy, in particular a binary chromium-aluminum alloy, a binary chromium-nitrogen alloy or a binary chromium-titanium alloy;
the cladding element is a cladding tube, in particular a cladding tube for nuclear fuel rod.

The present disclosure further relates to a nuclear fuel element comprising nuclear fuel arranged inside a cladding formed by at least one cladding element as defined above.

The present disclosure further relates to a nuclear fuel rod comprising nuclear fuel arranged inside a cladding formed by a tubular cladding element as defined above, closed by plugs at the ends thereof.

The present disclosure further relates to a method for manufacturing a cladding element as defined above, comprising, obtaining the substrate and then depositing the protective coating onto the substrate by physical vapor deposition by sputtering of a target or by physical deposition by cold spraying.

The deposition of the protective coating by physical vapor deposition or by physical cold spray deposition, in particular by magnetron sputtering, is used for obtaining the columnar microstructure while at the same time, limiting the density of microdroplets on the surface of the protective coating.

According to particular embodiments, the manufacturing process comprises one or a plurality of the following optional features, taken individually or in all technically possible combinations:
the deposition is carried out by physical vapor deposition by magnetron sputtering;
the substrate is plate-shaped and the deposition step is carried out in such a way that the rate of deposition of the protective coating on the substrate is between 1 μm/h and 30 μm/h;
the substrate is a tube which has a central axis, and the deposition step is carried out by rotating the substrate about the central axis thereof and in such a way that the rate of deposition of the protective coating on the substrate is between 1/π μm/h and 30/π μm/h;
the deposition is carried out by physical vapor deposition by supplying the target with direct current so as to obtain a current density comprised between 0.0005 A/cm² and 0.1 A/cm² on the target or with pulsed current with current peaks so as to obtain a density of current comprised between 0.01 A/cm² and 5 A/cm² on the target during current peaks;
the deposition is carried out by physical vapor deposition with an electrical bias voltage on the substrate with respect to the target during physical vapor deposition, which is negative and comprised between −10 V and −200 V.

### BRIEF SUMMARY OF THE DRAWINGS

The present disclosure and the advantages of the present disclosure will better understood upon reading the following description, given only as a non-limiting example, and made with reference to the enclosed drawings, wherein:

FIG. 1 is a schematic view in longitudinal section of a nuclear fuel rod;

FIG. 2 is a schematic cross-sectional view of a cladding tube of a nuclear fuel rod;

FIG. 3 is a micrograph of a section of a protective coating deposited on a substrate;

FIG. 4 is a schematic view of a region of the surface of a protective coating, illustrating the presence of microdroplets;

FIG. 5 is a schematic view of an assembly for depositing a coating on a substrate by physical vapor deposition, and

FIGS. 6 and 7 are photographs—taken under a microscope—of the surface of protective coatings deposited onto a substrate by physical vapor deposition; and

FIG. 8 is a photograph—taken under a microscope—of the surface of a protective coating deposited onto a substrate by physical vapor deposition by cathodic arc evaporation, where the substrate is heated.

### DETAILED DESCRIPTION

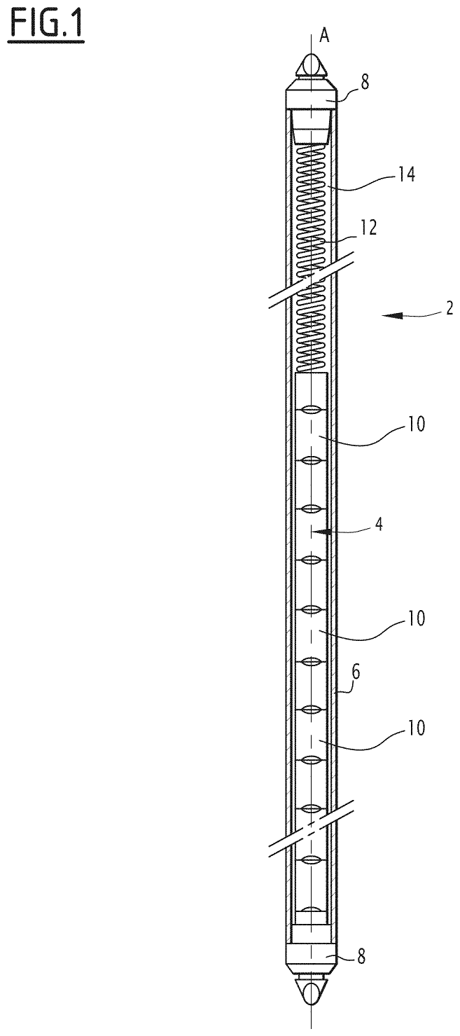

FIG. 1 shows a nuclear fuel rod 2 intended e.g. for being used in a light water reactor, in particular a pressurized water reactor (PWR) or a boiling water reactor (BWR), a “VVER” reactor, a “RBMK” reactor, or a heavy water reactor, e.g. a “CANDU” reactor.

The nuclear fuel rod 2 has the shape of a rod elongated along a rod axis A.

The nuclear fuel rod 2 comprises a cladding 4 containing nuclear fuel.

The cladding 4 comprises a tubular cladding element 6 (or “cladding tube”), extending along the rod axis A and closed by a plug 8 at each of the ends thereof.

The nuclear fuel is in the form of a stack of pellets 10 stacked axially inside the cladding element 6, each pellet 10 containing fissile material. The stack of pellets 10 is also called a “fissile column”.

The nuclear fuel rod 2 comprises a spring 12 arranged inside the cladding element 6, between the stack of pellets 10 and one of the plugs 8, for pushing the stack of pellets 10 toward the other plug 8.

There is empty space or plenum 14 between the stack of pellets 10 and the plug on which the spring 12 bears.

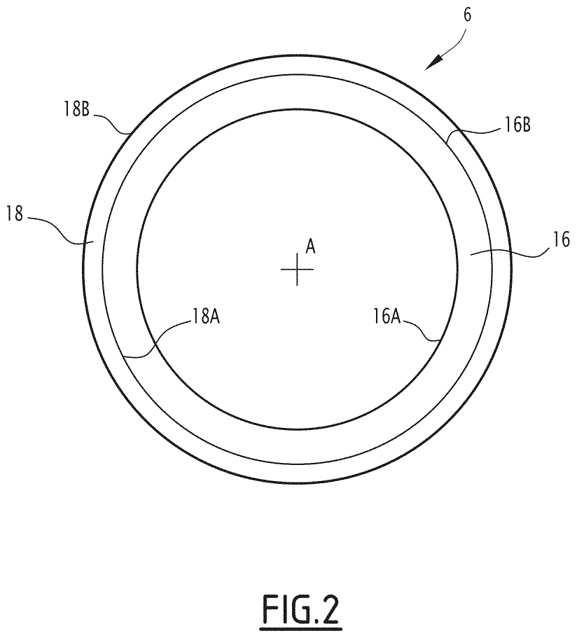

As shown in FIG. 2 which is a cross-sectional view of the cladding element 6, the latter comprises a substrate 16 covered on the outside with a protective coating 18.

The substrate 16 has an inner surface 16A oriented toward the inside of the cladding 4 and an outer surface 16B oriented toward the outside of the cladding 4. The protective coating 18 covers the outer surface 16B of the substrate 16 so as to protect same from the outer environment.

The cladding element 6 is here a tube, and, correspondingly, the substrate 16 has here a tubular shape.

The substrate 16 is e.g. made of a material containing zirconium.

In the present context, a material containing zirconium refers to a material made of pure zirconium or an alloy containing zirconium.

A pure zirconium material is a material comprising at least 99% by weight of zirconium.

An alloy containing zirconium is an alloy comprising at least 95% by weight of zirconium. The alloy containing zirconium is chosen, e.g., from one of the known alloys such as M5, ZIRLO, E110, HANA and N36.

The substrate 16 has e.g. a thickness comprised between 0.4 mm and 1 mm. The thickness of the substrate 16 is the distance between the inner surface 16A and the outer surface 16B of the substrate 16.

The protective coating 18 is a thin layer having e.g. a thickness strictly less than the thickness of the substrate 16.

The protective coating 18 has e.g. a thickness comprised between 5 μm and 25 μm, in particular, a thickness comprised between 10 μm and 20 μm. The thickness of the protective coating 18 is taken perpendicular to the surface on which the protective coating 18 is deposited, here the outer surface 16B of the substrate 16.

Preferentially, the protective coating 18 is the outermost layer of the cladding element 6. The protective coating 18 is in contact with the exterior environment.

The protective coating 18 is made of a material containing chromium.

In the present context, a material containing chromium refers to a pure chromium material or an alloy containing chromium.

A pure chromium material is a material comprising at least 99% by weight of chromium.

An alloy containing chromium is an alloy comprising at least 85% by weight of chromium.

In one embodiment, the material containing chromium is an alloy containing chromium chosen from: a binary chromium-aluminum alloy (CrAl), a binary chromium-nitrogen alloy (CrN) and a binary chromium-titanium alloy (CrTi).

The protective coating 18 comprises a single layer made of a material containing chromium or a plurality of overlaid layers made of a material containing chromium, preferentially of the same material containing chromium.

The structure of the protective coating 18 in a plurality of overlaid layers results e.g. from the deposition process used to deposit the protective coating 18 onto the substrate 16.

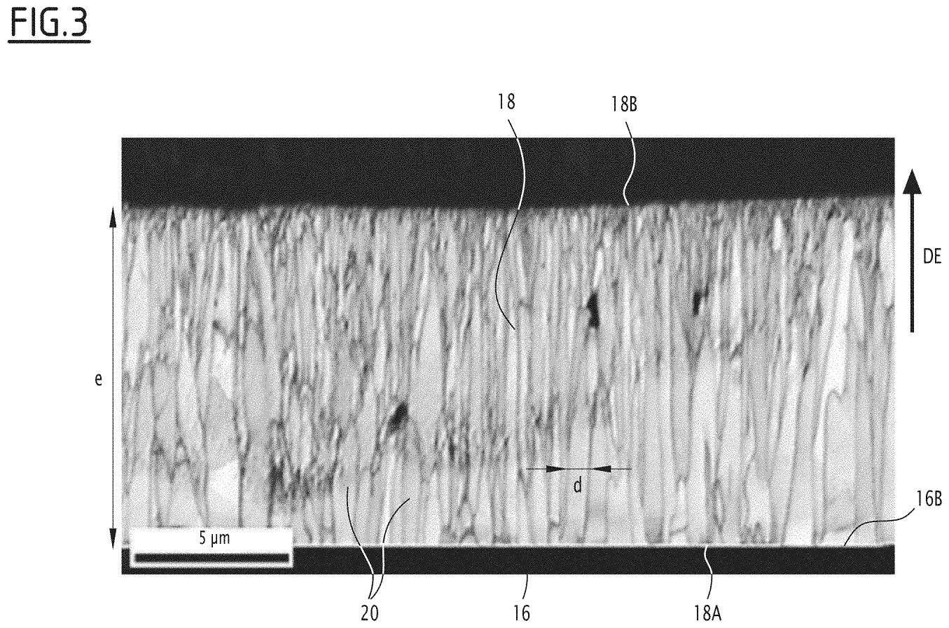

As shown in FIG. 3, the protective coating 18 has a columnar microstructure. In other words, the microstructure of the protective coating 18 has columnar grains 20, i.e. grains which have the general shape of a cylinder elongated along a direction of extension DE perpendicular to the surface on which the protective coating 18 is deposited, here the outer surface 16B of the substrate 16.

Each columnar grain 20 has a height, taken along the direction of extension DE of the columnar grain 20.

Each columnar grain 20 has a diameter. The diameter of a columnar grain 20 is e.g. measured on a micrograph by measuring the width of the columnar grain 20, i.e. dimension thereof perpendicular to the direction of extension thereof.

Of course, each columnar grain 20 is not perfectly cylindrical and has a diameter which can vary along the columnar grain 20.

Furthermore, the columnar grains 20 do not all have the same diameter.

It is possible to determine a mean diameter of the columnar grains 20 of the protective coating 18 at the interface between the substrate 16 and the protective coating 18 (i.e. near the inner surface 18A of the protective coating 18), as the sum of the diameters of columnar grains 20 visible on a micrograph of the protective coating 18 at the interface between the substrate 16 and the protective coating 18, divided by the number of columnar grains 20 considered.

It is also possible to determine a mean diameter of the columnar grains 20 of the protective coating 18 near the outer surface 18B, as the sum of the diameters of the columnar grains 20 visible on a micrograph of the protective coating 18 near the outer surface 18B, divided by the number of columnar grains 20 considered.

Preferentially, at the interface between the substrate 16 and the protective coating 18, the columnar grains 20 have a mean diameter less than or equal to 1 μm, in particular a mean diameter less than or equal to 0.5 μm.

The very fine columnar grains 2 at the interface between the substrate 16 and the protective coating 18 provide good cohesion of the protective coating 18 on the substrate 16.

Moving away from the interface between the substrate 16 and the protective coating 18, the diameter of the columnar grains 20 tends to increase.

Preferentially, near the outer surface 18B of the protective coating 18, the columnar grains 20 have a mean diameter comprised between 0.05 μm and 5 μm, preferentially between 0.1 μm and 2 μm.

The relatively fine columnar grains 20 on the outer surface 18B of the protective coating 18 limit the weakening and the risk of peeling on the protective coating 18.

During a deposition of the coating 18, in particular, physical vapor deposition, microdroplets 22 may appear on the outer surface 18B of the protective coating 18.

Preferentially, the density of microdroplets 22 on the outer surface 18B of the coating 18 is less than or equal to 100 per mm², in particular less than or equal to 10 per mm².

The density of microdroplets 22 at the outer surface 18B of the protective coating 18 is determined e.g. by observation under an optical or electron microscope of a given reference region of the outer surface 18B, preferentially on a sample which is representative of the homogeneity of the outer surface 18B.

The density of microdroplets 22 on the outer surface 18B of the protective coating 18 is e.g. determined as the number of microdroplets 22 present in the reference region of the outer surface 18B of the protective coating 18 divided by the area of the reference region.

The reference region represents e.g. a fraction of the outer surface 18B of the protective coating 18. The area of the reference region is large enough for the measurement to be representative. Preferentially, the area of the reference region is greater than or equal to 10 mm².

Preferentially, the microdroplets 22 present on the outer surface 18B have a diameter less than or equal to 20 μm. In other words, the outer surface 18B is free of microdroplets with a diameter greater than 20 μm.

Each microdroplet 22 present on the outer surface 18B of the protective coating 18 enhances, in operation, the infiltration of cooling fluid (typically water) along the boundaries between the microdroplet 22 and the columnar grains 22, which reduces the corrosion resistance of the cladding element and the oxidation resistance of the cladding element, in particular at high temperatures (typically 280° C. to 350° C. in normal operation and between 800° C. and 1200° C. under accident conditions, in a pressurized water reactor).

Furthermore, each microdroplet 22 defines a discontinuity in the microstructure of the protective coating 18, which weakens the protective coating 18 by forming a point of weakness and by being likely to initiate cracks in the protective coating 18.

In addition, each microdroplet 22 locally affects the formation of the microstructure of the protective coating 18, generally by causing the growth of grains of larger diameter under the microdroplet 22.

Limiting the density of the microdroplets 22 present on the outer surface 18B of the protective coating 18 thus makes it possible to improve the resistance of the cladding element 6.

Moreover, the large microdroplets can be the source of crack generation. The absence of any microdroplet with a diameter greater than 20 μm limits such risk. The protective coating 18 is deposited so as to avoid the formation of any microdroplet with a diameter greater than 20 μm.

The cladding element 6 described above is a cladding tube for producing a nuclear fuel rod 2 comprising nuclear fuel arranged inside the cladding element 6 which is sealed by a plug at each of the ends thereof.

In another embodiment, the cladding element 6 is plate-shaped, e.g. so as to form a plate-shaped nuclear fuel element 2 comprising a layer of nuclear fuel interposed (i.e. sandwiched) between two plate-shaped cladding elements 6.

Such a plate-shaped cladding element 6 is produced in a manner similar to what was described above, in particular with regard to the material of the substrate 16, the material of the protective coating 18, the thickness of the substrate 16, the thickness of the protective coating 18, the microstructure of the protective coating 18 and the limitation of the droplets onto the outer surface 18B of the protective coating 18.

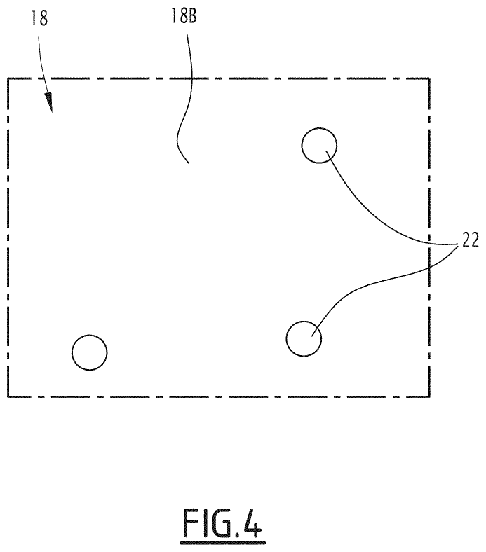

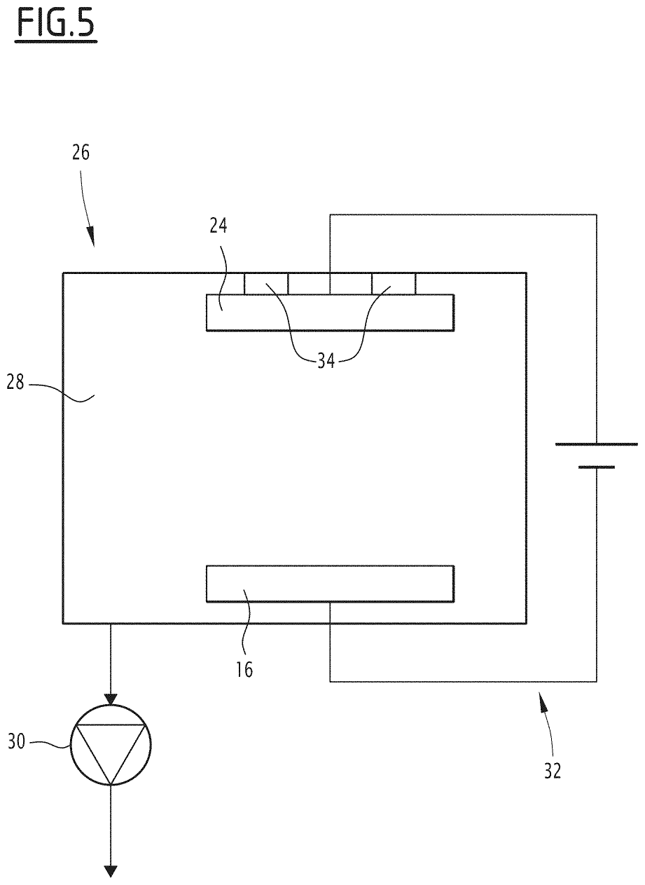

A method of manufacturing the cladding element 6 will now be described with reference to FIG. 4.

The manufacturing process comprises a step of obtaining the substrate 16. When the cladding element 6 is a cladding tube for a nuclear fuel rod, the substrate 16 is a tube, which has e.g. an outer diameter comprised between 8 mm and 15 mm, in particular between 9 mm and 13 mm, and/or a length comprised between 1 m and 5 m, in particular between 2 m and 5 m. Such a tube is e.g. produced in a known manner by pilgrim rolling, from a tubular blank of larger diameter and of smaller length than the tube.

The manufacturing process then comprises a step of depositing the coating on the outer surface 16B of the substrate 16, e.g. by physical vapor deposition by sputtering.

During the deposition step, the substrate 16 and a target 24, which is made of a material suitable for forming the protective coating 18, are placed in a rarefied atmosphere, formed e.g. of a neutral gas, such as argon, and an electric potential difference is generated between the target 24 and the substrate 16, the target 24 defining a cathode and the substrate 16 defining an anode (the target 24 is brought to an electric potential higher than the electrical potential of the substrate 16).

Under the effect of the potential difference between the substrate 16 and the target 24, an electric field is generated between the substrate 16 and the target 24 in the rarefied atmosphere, leading to producing a plasma containing electrically charged particles (electrons, ions, etc.), which are precipitated on the target 24 under the effect of the electric field and detach atoms from the target 24 (i.e. the target 24 is sputtered, hence the term cathode sputtering), the atoms detached from the target 24 being deposited afterwards on the substrate 16.

In the case of a protective coating 18 made of pure chromium, the target 24 is e.g. made of pure chromium. In the case of a protective coating 18 made of a chromium alloy, in particular a binary chromium alloy as indicated above, the target 24 is e.g. made of a chromium alloy having different proportions, but allowing a protective coating to be deposited with the intended proportions (e.g. a target made of chromium-aluminum alloy with 15% by weight of aluminum so as to obtain a protective coating made of chromium-aluminum alloy with 10% by weight of aluminum).

As illustrated in FIG. 4, the deposition step is carried out by means of a physical vapor deposition installation 26, comprising a chamber 28, the target 24 arranged inside the chamber 28, and a pump 30, the inlet of which is fluidically connected to the chamber 28 so as to generate a rarefied atmosphere in the chamber 26, and an electric circuit 32 for generating a potential difference between the target 24 and the substrate 16 introduced into the chamber 28.

During the deposition step, the substrate 16 is introduced into the chamber 28, a rarefied atmosphere is created inside the chamber 28 by means of the pump 30, and the potential difference between the target 24 and the substrate 14 is generated by the electric circuit 32, which allows the physical vapor deposition to be carried out.

Preferentially, the physical vapor deposition is carried out by magnetron sputtering.

In such a case, a magnetic field is generated, preferentially at least close to the target 24.

The provision of a magnetic field makes it possible to better control the trajectory of the electrically charged particles reaching the target 24, which leads to a better controlled rate of deposition of the protective coating 18, in particular, a faster rate of deposition of the protective coating 18.

The magnetic field is generated e.g. by one or more permanent magnets 34, as illustrated in FIG. 4, and/or one or more electromagnets.

Furthermore, a physical vapor deposition by sputtering, in particular by magnetron sputtering, makes it possible to carry out a deposition exhibiting satisfactory uniformity, while at the same time limiting the occurrence of microdroplets 22 on the outer surface 18B of the protective coating 18.

Preferentially, when the substrate 16 has a tubular shape, in particular a tube with symmetry of revolution about a central axis, as is the case for a substrate 16 for a cladding tube of a nuclear fuel rod, the substrate 16 is rotated about the central axis thereof during the deposition step.

In this way, a uniform deposition can be carried out over the entire circumference of the outer surface 16B of the tube-shaped substrate 16.

During the deposition step, preferentially, the protective coating 18 is deposited on the tube-shaped substrate with a central axis by rotating the substrate 16 about the central axis and in such a way that the rate of deposition of the protective coating 18 onto the substrate 16 is between 1/π μm/h and 30/π μm/h.

It is possible to provide a cladding element 6 in with the shape of a plate, so that the outer surface 16B of the substrate 16 is substantially flat. Such a cladding element 6 can be used for forming a nuclear fuel element with the general shape of a plate, comprising nuclear fuel interposed (or sandwiched) between two cladding elements 6 with the shape of a plate.

In the case of a cladding element 6 in the shape of a plate, the deposition step is carried out without any rotation of the substrate 16.

Preferentially, the deposition of the protective coating 18 on a plate-shaped substrate is carried out in such a way that the rate of deposition of the protective coating 18 on the substrate 16 is between 1 μm/h and 30 μm/h.

The microstructure of the protective coating 18 which will be obtained depends on the rate of deposition of the protective coating 18.

The above-proposed rates of deposition can be used for obtaining a desired microstructure, i.e. a columnar microstructure with columnar grains with a small diameter at the interface between the substrate 18 and the protective coating 18, and a not too high diameter at the outer surface 18B of the protective coating, as mentioned above.

The rate of deposition of the protective coating 18 by physical vapor deposition by sputtering, in particular by magnetron sputtering, depends in particular on the density of current flowing across the target 24 and on the bias voltage of the substrate, i.e. the difference between the electrical potential of the substrate 16 and the electrical potential of the target 24 during deposition.

Furthermore, the physical vapor deposition can be carried out with a direct current density (i.e. by applying a direct electric current to the target 24) or a pulsed current density (i.e. by applying a pulsed electric current comprising pulses).

The current density of the target is the amount of the current flowing through the target divided by the area of the active surface of the target, i.e. the surface of the target which is oriented toward the substrate 16 and which receives the charged particles of the plasma projected onto the target 24.

In one embodiment, the protective coating 18 is deposited by supplying the target 24 with a direct current so as to obtain a current density of between 0.0005 A/cm² and 0.1 A/cm² at the target 24, preferentially comprised between 0.0005 A/cm² and 0.05 A/cm², or by supplying the target 24 with a pulsed current with current peaks so as to obtain at the target 24 a current density comprised between 0.01 A/cm² and 5 A/cm² during current peaks (i.e. peak current density), preferentially between 0.01 A/cm² and 0.5 A/cm².

The target power density is the electrical power deposited over the target divided by the area of the active surface of the target.

In one embodiment, the protective coating 18 is deposited by supplying the target 24 with a direct current so as to obtain a power density comprised between 0.5 W/cm² and 100 W/cm2 at the target 24, preferentially a power density comprised between 0.5 W/cm² and 50 W/cm², or by supplying the target 24 with a pulsed current with current peaks so as to obtain a power density comprised between 10 W/cm2 and 50,000 W/cm² at the target 24 (i.e. the peak power density), preferentially a power density comprised between 10 W/cm² and 5,000 W/cm².

Preferentially, the electrical bias voltage of the substrate 16 with respect to the target 24 during physical vapor deposition is negative and is comprised between −10 V and −200 V, more preferentially between −50 V and −150 V.

In a preferred embodiment, the deposition is carried out with a pulsed current with one or a plurality of the following parameters:
the mean power density (the time average of the electrical power density deposited over the target 24) is comprised between 1 W/cm² and 5 W/cm²;
the peak power density (the electric power across the target 24 at each current pulse per unit area of the target 24) is comprised between 30 W/cm² and 100 W/cm²;
the frequency of the current pulses is comprised between 50 Hz and 5000 Hz;
the duration of the current pulses is comprised between 10 μs and 50 μs;
the physical vapor deposition is carried out in an atmosphere consisting of an inert gas, in particular an atmosphere consisting of argon (Ar);
the pressure inside the chamber wherein the physical vapor deposition is carried out is comprised between 0.1 Pa and 0.4 Pa; and/or
the distance between the substrate 16 and the target 24 is comprised between 50 mm and 200 mm, more preferentially between 80 mm and 140 mm.

The observance of one or a plurality of the above-indicated preferred ranges allows the low droplet density to be obtained.

Preferentially, the physical vapor deposition is carried out onto the substrate 16 without any heat input other than the heat input resulting from the bombardment of the substrate 16 with the particles (atoms, ions, etc.) stripped from the target 24 due to the physical vapor deposition.

In particular, the substrate 16 is not heated by means of a heating system. In this way, the risk of exceeding the phase transition temperature of the material of the substrate 16, is limited.

Physical vapor deposition by magnetron sputtering can be carried out according to one of the following techniques or a combination of at least two of the following techniques: direct current (DC) magnetron sputtering, pulsed direct current (or DC pulsed) magnetron sputtering, High Power Impulse Magnetron Sputtering (HiPIMS or HPMS), Magnetron Sputtering Bi-polar (MSB), Dual Magnetron Sputtering (MSB), Dual Magnetron Sputtering (Magnetron sputtering Bi-polar), Dual Magnetron Sputtering (DMS), Unbalanced Magnetron (UBM) Sputtering.

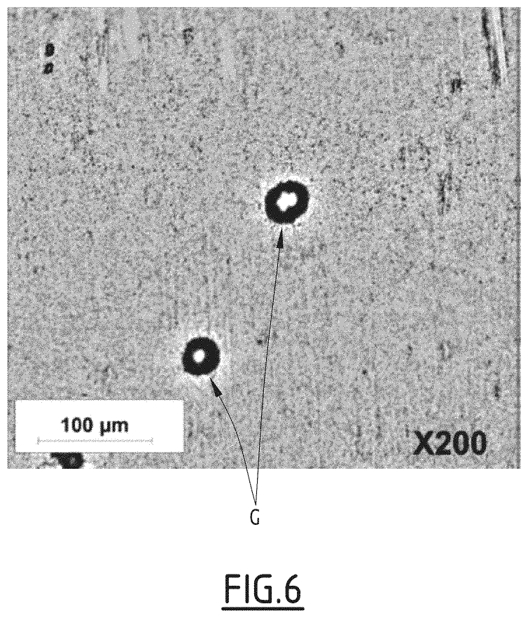

FIGS. 6 to 8 are photographs taken under a microscope of the surface of protective coatings 18 deposited onto a substrate 16 by physical vapor deposition by magnetron sputtering with pulsed current, under an argon atmosphere, with different sets of parameters, as shown in Table 1 below:

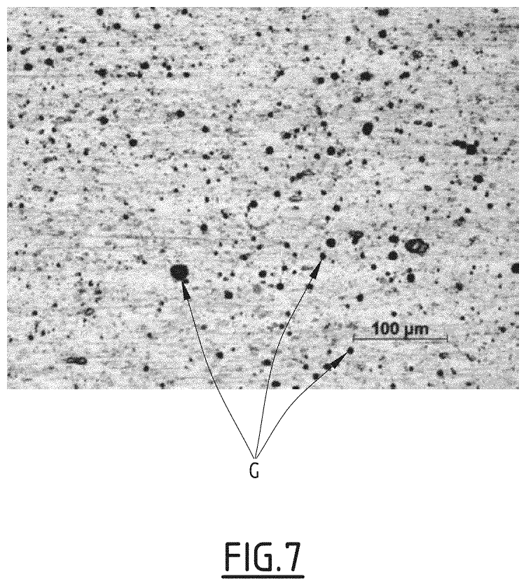

TABLE 1

| | | | Example 2 | | Example 3 | |
|---|---|---|---|---|---|---|
| | Example 1 | | (FIGS. 6) | | (FIG. 7) | |
| Pressure inside the | 0.2 | Pa | 0.2 | Pa | 0.5 | Pa |
| chamber | | | | | | |
| Distance between target | 80 | mm | 140 | mm | 100 | mm |
| and substrate (mm) | | | | | | |
| Deposition coating rate | 2 | μ/h | 3 | μ/h | 1.5 | μ/h |
| Bias voltage (V) | −50 | V | −100 | V | − 100 | V |
| Peak power density | 30 | W/cm2 | 70 | W/cm2 | 350 | W/cm2 |
| Duration of current | 50 | μs | 20 | μs | 35 | μs |
| pulses | | | | | | |
| Frequency of | 650 | Hz | 2000 | Hz | 650 | Hz |
| current pulses | | | | | | |

Example 1 and example 2 are carried out observing the above-indicated physical vapor deposition parameters, whereas example 3 is not carried out observing all said parameters.

As can be seen in FIG. 6 which is a view of a sample produced according to example 2, the protective coating 18 has few droplets G on the outer surface 18B thereof.

In the example 2, the protective coating 18 has on the outer surface 18B thereof, a microdroplet density of 50 per mm².

Example 1 gave a result similar to the result of example 2, the protective coating 18 having on the outer surface 18B thereof, a microdroplet density of 50 per mm².

The protective coating 18 of example 3 shown in FIG. 7 was also produced by physical vapor deposition by magnetron sputtering, but outside the recommended ranges, in particular, for the pressure and the peak power density.

The microdroplet density is—in this case—about 2,500 microdroplets per mm², which is much higher than the maximum sought microdroplet density, which is 100 microdroplets per mm².

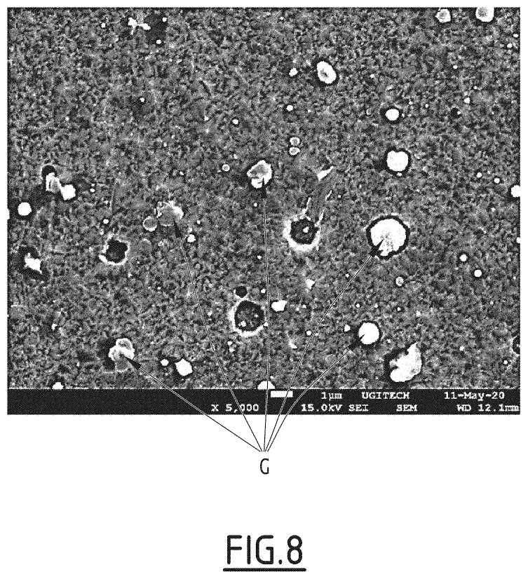

The protective coating 18 of the example shown in FIG. 8 was manufactured by physical vapor deposition by arc sputtering with heated substrate and parameters which are different from the parameters of magnetron sputtering.

As can be seen in FIG. 8, in this example, the protective coating 18 has on outer surface 18B thereof, a microdroplet density greater than 10,000 per mm².

It should be noted that the scales of the photographs of FIGS. 6 to 8 are different.

Deposition of the protective coating by physical vapor deposition by magnetron sputtering is preferred, but the present disclosure is not limited to such a deposition technique.

As a variant, the protective coating can be deposited according to another technique, e.g. by physical cold spray deposition.

The present disclosure makes it possible to obtain a nuclear fuel cladding element which has good resistance to oxidation and hydriding, in a normal operation of the nuclear reactor and under an accident condition, e.g. during loss of cooling fluid accident.

What is claimed is:

1-24. (canceled)

25. A nuclear fuel cladding element, the cladding element comprising:
a substrate made of a material containing zirconium; and
a protective coating covering the substrate on an outside, the protective coating being made of a material containing chromium, the protective coating having a columnar microstructure composed of columnar grains and has on an outer surface thereof a microdroplet density of less than 100 per mm².

26. The cladding element according to claim 25, wherein next to and/or at an interface between the cladding element and the protective element, the columnar grains have a mean diameter less than or equal to 1 μm, preferentially less than or equal to 0.5 μm.

27. The cladding element according to claim 25, wherein next to and/or on the outer surface of the protective element, the columnar grains have a mean diameter between 0.05 μm and 5 μm, preferentially between 0.1 μm and 2 μm.

28. The cladding element according to claim 25, wherein the microdroplets have a diameter less than or equal to 20 μm.

29. The cladding element according to claim 25, wherein the protective coating has a thickness comprised between 5 μm and 25 μm.

30. The cladding element according to claim 25, wherein the material containing chromium is pure chromium, an alloy containing zirconium or a binary chromium alloy.

31. The cladding element according to claim 25, wherein the cladding element is a cladding tube of a nuclear fuel rod.

32. A nuclear fuel element comprising nuclear fuel disposed within a cladding consisting of at least one cladding element according to claim 25.

33. A nuclear fuel rod comprising:
a cladding consisting of the cladding element according to claim 25; and
nuclear fuel arranged within the cladding, the cladding being closed by plugs at ends thereof.

34. A method of manufacturing the cladding element according to claim 25, comprising:
obtaining the substrate and then depositing the protective coating onto the substrate by physical vapor deposition by sputtering of a target or by physical deposition by cold spraying.

35. The manufacturing method according to claim 34, wherein the deposition is carried out by physical vapor deposition by magnetron sputtering.

36. The manufacturing method according to claim 34, wherein the substrate has a shape of a plate and the deposition step is carried out in such a way that a rate of deposition of the protective coating onto the substrate is comprised between 1 μm/h and 30 μm/h.

37. The manufacturing method according to claim 34, wherein the substrate is a tube which has a central axis, the deposition step being carried out by rotating the substrate about the central axis thereof and in such a way that the rate of deposition of the protective coating onto the substrate is comprised between 1/π μm/h and 30/π μm/h.

38. The manufacturing method according to claim 34, wherein the deposition is carried out by physical vapor deposition by supplying the target with pulsed current with current peaks.

39. The manufacturing method according to claim 38, wherein the deposition is carried out with an average power density comprised between 1 W/cm2 and 5 W/cm2;

[symbol]

40. The manufacturing method according to claim 38, wherein the deposition is carried out with a peak power density comprised between 30 W/cm2 and 100 W/cm2;

[symbol]

41. The manufacturing method according to claim 38, wherein the deposition is carried out with a frequency of the current pulses comprised between 50 Hz and 5000 Hz;

[symbol]

42. The manufacturing method according to claim 38, wherein the deposition is carried out with a current pulse duration comprised between 10 μs and 50 μs;

[symbol]

43. The manufacturing method according to claim 38, wherein the deposition is carried out under a pressure comprised between 0.1 Pa and 0.4 Pa.

44. The manufacturing method according to claim 38, wherein the deposition is carried out with a distance between the substrate and the target comprised between 50 mm and 200 mm, more preferentially between 80 mm and 140 mm.

45. The manufacturing method according to claim 34, wherein the deposition is carried out by physical vapor deposition by supplying the target with direct current so as to obtain a current density comprised between 0.0005 A/cm2 and 0.1 A/cm2 on the target, preferentially between 0.0005 A/cm2 and 0.05 A/cm2, or in pulsed current with current peaks so as to obtain a current density comprised between 0.01 A/cm2 and 5 A/cm2 on the target during current peaks, preferentially between 0.01 A/cm2 and 0.5 A/cm2.

46. The manufacturing method according to claim 34, wherein the deposition of the protective coating is carried out by supplying the target with a direct current so as to obtain a power density comprised between 0.5 W/cm2 and 100 W/cm2 for the target, preferentially a power density comprised between 0.5 W/cm2 and 50 W/cm2 or with a pulsed current with current peaks so as to obtain a peak power density comprised between 10 W/cm² and 50.000 W/cm² at the target.

47. The manufacturing method according to claim 34, wherein the deposition is carried out by physical vapor deposition with an electrical bias voltage of the substrate with respect to the target during physical vapor deposition, which is negative and comprised between −10 V and −200 V.

48. The manufacturing method according to claim 34, wherein the deposition is carried out in an atmosphere consisting of an inert gas.
